(19) United States
(12) Patent Application Publication
(10) Pub. No.: US 2017/0353641 A1
(43) Pub. Date: Dec. 7, 2017

(54) ILLUMINATOR WITH ENGINEERED ILLUMINATION PATTERN

(71) Applicant: INTEL CORPORATION, Santa Clara, CA (US)

(72) Inventors: Richmond F. Hicks, Aloha, OR (US); Khaled Ahmed, Anaheim, CA (US)

(73) Assignee: INTEL CORPORATION, Santa Clara, CA (US)

(21) Appl. No.: 15/275,736

(22) Filed: Sep. 26, 2016

Related U.S. Application Data
(60) Provisional application No. 62/346,932, filed on Jun. 7, 2016.

(51) Int. Cl. H04N 5/225; H01L 33/30; H01L 33/62; H01L 33/00; H01L 33/60; H01L 33/06

(52) U.S. Cl. CPC H04N 5/2256; H01L 33/60; H01L 33/06; H01L 33/62; H01L 33/0062; H01L 33/30; H01L 2933/0058; H01L 2933/0066

(57) ABSTRACT

Techniques for tuning the illumination pattern of a Light Emitting Diode (LED) are described. An example image capture system incorporates an LED with an integrated micro-reflector. The example image capture system includes a camera to capture an image of an object and a Light Emitting Diode (LED) to emit light for illuminating the object. The LED includes a light emitting layer and a window layer made of transparent semiconductor material disposed over the light emitting layer. The shape of the window layer creates a plurality of reflectors that generate a specified illumination pattern that reduces the effect of illuminance distortions created by the image capture system.

### CROSS-REFERENCE TO RELATED APPLICATION

The present application claims the benefit of U.S. Provisional Patent Application Ser. No. 62/346,932 by Hicks, et al., which is titled “Illuminator with Engineered Illumination Pattern” and was filed Jun. 7, 2016, the disclosure of which is incorporated herein by this reference as though fully set forth herein.

### TECHNICAL FIELD

The present disclosure relates generally to techniques for fabricating an illuminator. More specifically, the present techniques relate to an illuminator that is fabricated with a built-in micro-reflector that enables the illuminator to produce a desired illumination pattern.

### BACKGROUND ART

There are several reasons why an electronic device such as a smart phone would be equipped with the ability to the project light. For example, an illuminator might be used to project light for the purpose of capturing an image. In some devices, image capture can be used for biometric identification based on the unique pattern of a person's facial features or an image of the person's iris. Such biometric identification techniques may work better if the camera delivers uniform images from the combination of illumination and image capture hardware.

### BRIEF DESCRIPTION OF THE DRAWINGS

FIG. 1 is a cross sectional view of an example LED with micro-reflectors.

FIG. 2 is a top view of the example LED shown in FIG. 1.

FIG. 3 is an example radiation pattern that may be achieved using an LED with micro-reflectors.

FIG. 4 is a cross sectional view of another example LED with micro-reflectors.

FIG. 5 is a top view of the example LED shown in FIG. 4.

FIG. 6 is a cross sectional view of another example LED with built-in features that enable the LED to exhibit a desired illumination pattern.

FIG. 7 is a cross sectional view of another example LED with built-in features that enable the LED to exhibit a desired illumination pattern.

FIG. 8 is a block diagram of an electronic device equipped with one of the LEDs described herein.

FIG. 9 is a process flow diagram summarizing an example method of fabricating an LED with micro-reflectors.

FIG. 10 is a process flow diagram summarizing another example method of fabricating an LED with built-in features that enable the LED to exhibit a specified illumination pattern.

FIG. 11 is a process flow diagram summarizing another example method of fabricating an LED with built-in features that enable the LED to exhibit a specified illumination pattern.

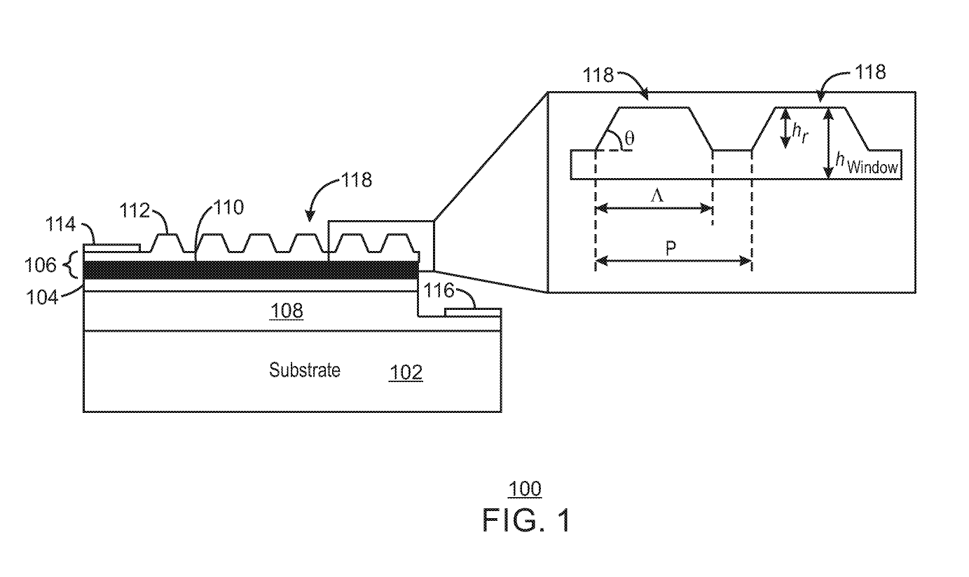

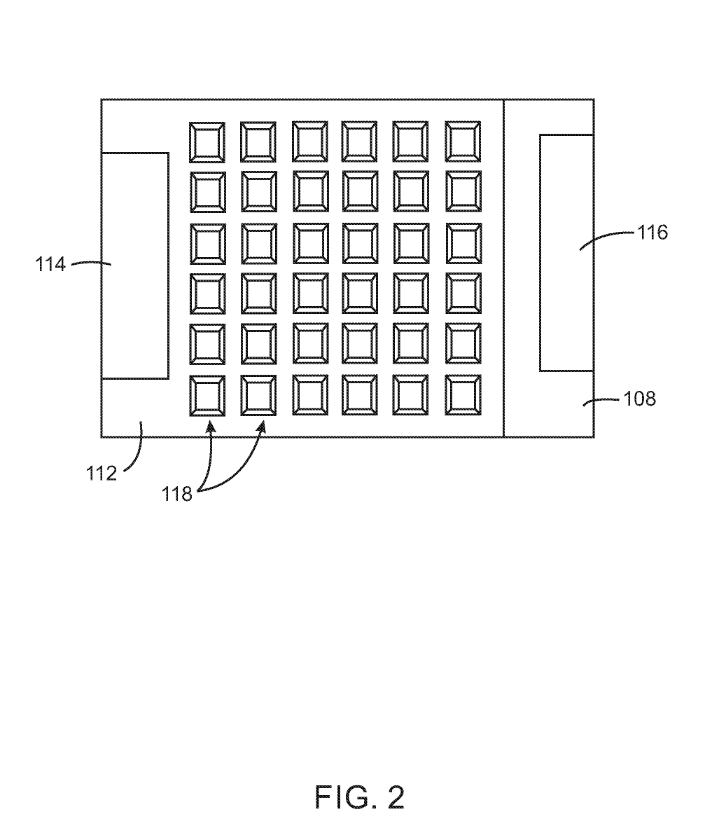

The same numbers are used throughout the disclosure and the figures to reference like components and features. Numbers in the 100 series refer to features originally found in FIG. 1; numbers in the 200 series refer to features originally found in FIG. 2; and so on.

### DESCRIPTION OF THE EMBODIMENTS

The subject matter disclosed herein relates to techniques for adjusting the illumination pattern of an illuminator. The illuminators described herein may be useful in in facial recognition systems, such as face login and others. Some usages such as face recognition and others may work more effectively with a controlled illumination pattern that generates an image with the specific visual characteristics. For example, some image capture systems suffer from a loss of illuminance toward the edges and corners of a captured image. Various factors contribute to loss of illuminance at the edges of the image, including the directionality of the illuminator, lens shading, image sensor aperture and angular effects of light filters. The loss of signal at the edges corresponds to a loss of signal-to-noise (SNR) in the corners, which may cause poor performance in some systems.

The techniques described herein optimize the projection pattern of a Light Emitting Diode (LED) illuminator by adapting the physical shape of the LED surface. The LED illuminator described herein has an illumination pattern that projects more light energy toward the edges of the scene being imaged. Projecting more light to the edges can compensate for other components of the imaging system, resulting in the capture of a more even image.

The LED illuminator includes one or more micro-reflectors that distribute the light from the LED into the desired illumination pattern. The micro-reflectors are structural features of the LED as opposed to a separate component that is affixed over the LED such as a lens. The micro-reflectors are manufactured on the emitting surface of the LED. The radiation pattern of the LED can be controlled by controlling the physical parameters of the LED and the micro-reflectors as described further below. In some examples, the radiation pattern may be a pattern referred to herein as a “batwing” radiation pattern. The LED structures are described in further detail below. Furthermore, in the present disclosure, the term “reflect” is used to refer to any phenomenon by which a material changes the direction of light, including what is sometimes referred to as “refraction.” Thus, the micro-reflectors described herein may operate according to principles of reflection, refraction, or a combination of both.

In the following description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other.

FIG. 1 is a cross sectional view of an example LED with micro-reflectors. The LED 100 may be fabricated using any suitable semiconductor fabrication techniques. For example, the creation of various structures may be accomplished though deposition, removal, and patterning of structures. Deposition techniques include techniques such as chemical vapor deposition, electrochemical deposition, and others. The patterning of various features maybe accomplished through the use of photolithography. Modification of the electrical properties of the various structures may be accomplished using doping techniques such as ion implantation.

The LED illuminator of FIG. 1 includes a semiconductor substrate 102, a quantum well layer 104, a P-type layer 106, and an N-type layer 108. In some examples, the semiconductor substrate is gallium arsenide (GaAs) and the quantum well layer, P-type layer 106, and N-type layer 108 may be aluminum arsenide (AlAs) or aluminum gallium arsenide (AlₓGa₁₋ₓAs/Al_{y}Ga_{1-y}As, y>x). The P-type layer 106 and N-type layer 108 may be doped layers of wide-bandgap semiconductor material such as Al_{0.9}Ga_{0.1}As or AlAs. The quantum well layer 104 is the light emitting layer and may be a Multiple Quantum Well (MQL) that includes alternating layers of active material, for example, layers of aluminum gallium arsenide with different aluminum compositions. For example, the quantum well layer 104 may include layers made of 10 percent aluminum alternating with layers made of 35 percent aluminum. In some examples, the quantum well layer 104 includes ten layers of Al_{0.1}Ga_{0.9}As, where an Al_{0.1}Ga_{0.9}As layer is formed on an Al_{0.35}Ga_{0.65}As layer, and another Al_{0.35}Ga_{0.65}As layer is formed on the Al_{0.35}Ga_{0.65}As layer, and so on.

The P-type layer can include an etch stop layer 110 and a window layer 112. In some examples, the etch stop layer 110 may be omitted so that the P-type layer 106 includes only the window layer 112. Electrical contact pads 114 and 116 are disposed on top of the P-type layer 106 and the N-type layer 108 respectively. Application of a suitable voltage to the contact pads 114 and 116 causes light to be emitted from the quantum well layer 104.

The P-type layer 106, N-type layer 108, and the quantum well layer 104 layer may all be formed by epitaxial growth processes. After formation of the window layer 112, a pattern of reflective elements is defined using a lithographic or non-lithographic method. The dimensions of the pattern, i.e., the spacing between the reflectors, may be in the range of 5-10 micrometer. Any suitable wet etch process can be used to create the reflectors 118. Other configurations are possible and the present techniques are not limited to the specific materials described herein.

The light emitted by the quantum well 104 passes through the P-type layer 106, including the window layer 112. The window layer 112 is shaped to impart a specific illumination pattern on the light passing through it. The window layer 112 includes a grid of reflectors 118 that are formed by shaping the window layer 112, for example, through chemical etching of the window layer. In the example of FIG. 1, the reflectors are shaped like tetrahedrons. However, other shapes are possible including pyramids, semi-spherical, and others. The reflectors will tend to reflect light depending on the angle of incidence of the light against one of more surfaces of the window layer 112. In this way, the shapes of the reflectors 118 can control the relative intensity of the light passing through the window layer 112 at different angles, which determines the illumination pattern of the LED 100.

The illumination pattern of the LED 100 may be controlled by controlling the shape and arrangement of the reflectors 118. For example, the radiation pattern of the LED can be controlled by controlling the physical parameters shown in FIG. 1, including θ, Λ, P, hᵣ, and h_{window}. The dimensions of the various features will depend on the light wavelength of interest, for example, 5 to 10 times the longest wavelength of interest. In some examples, the height of the window, h_{window}, is approximately 10 microns.

FIG. 2 is a top view of the example LED shown in FIG. 1. As seen in FIG. 2, the LED 100 includes the P-type layer 106, the N-type layer 108, contact pads 114 and 116, and the window layer 112 which has been formed into a grid of reflectors 118. FIG. 2 shows a six-by-six grid of reflectors 118. However, the LED can include any suitable number of reflectors 118. Furthermore, the grid may have a different number of rows compared to the number of columns. The number of reflectors 118 will depend on the reflector size and the size of the LED 100 so that the reflectors 118 cover the complete surface of the LED 100. For an example LED that is 1 mm square and an example reflector size of 10 um, the LED 100 will include a 100 by 100 grid of reflectors 118.

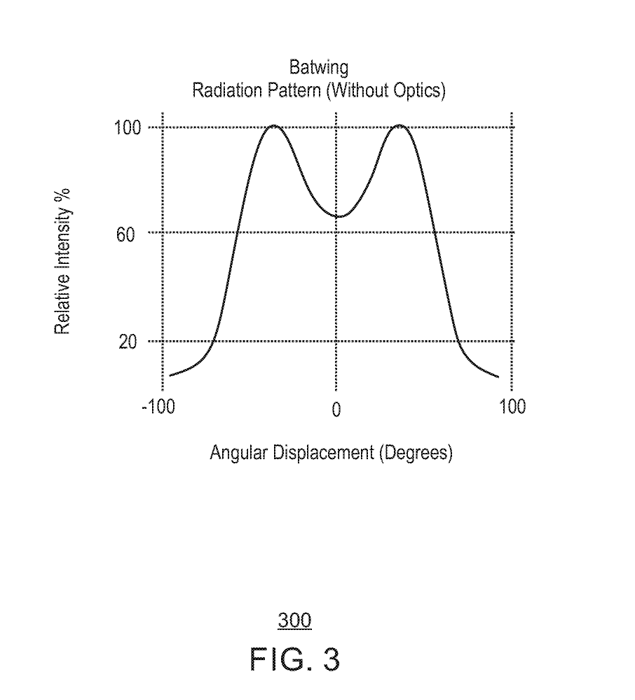

FIG. 3 is an example radiation pattern that may be achieved using an LED with micro-reflectors. The graph 300 shows the relative illumination intensity at different values of angular displacement. The angular displacement refers to the angle relative to a vector that is normal to the surface of the LED. The illumination pattern shown in FIG. 3 is referred to herein as a “batwing” pattern. The batwing illumination pattern may be defined by having two roughly equal peaks in a candela distribution plot with a valley between the peaks at about 0 degrees (normal to the light emitting surface of the LED). Accordingly, the illumination intensity at the edges of the radiation pattern are increased compared to an LED without micro-reflectors. In some examples, the illumination intensity of the LED may be about 50 percent greater at approximately +−30 degrees from normal compared to the illumination intensity at 0 degrees normal. The increased intensity at 30 degrees may help to correct for other effects that tend to reduce the illumination at the edges of the captured image. The illumination pattern shown in FIG. 3 is accomplished without the use of a lens or other light focusing device being disposed over the LED. Rather, the LED itself projects the light with the desired illumination pattern.

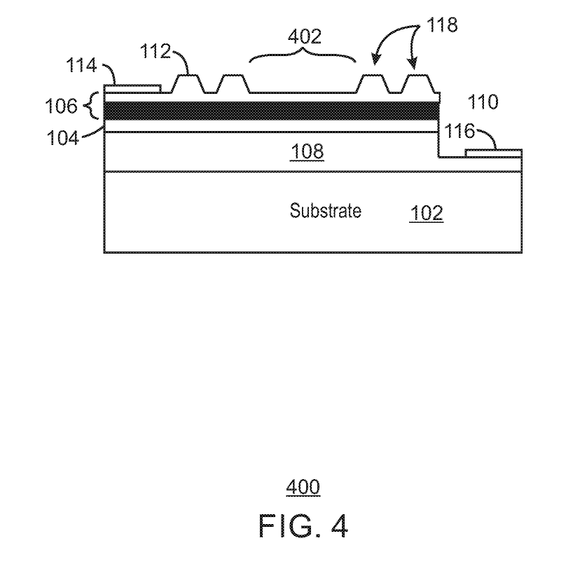

FIG. 4 is a cross sectional view of another example LED with micro-reflectors. The example LED 400 shown in FIG. 4 is similar to the LED 300 shown in FIG. 1 and includes the semiconductor substrate 102, the quantum well layer 104, the P-type layer 106, the N-type layer 108 and the contact pads 114 and 116. Additionally, the P-type layer includes the window layer 112 and an optional etch stop layer 110. However, window layer 112 of the LED 400 does not include reflectors 118 that are distributed evenly over the surface of the window layer 112. Rather, an open area 402 near the center of the window layer 112 is flat and void of reflectors.

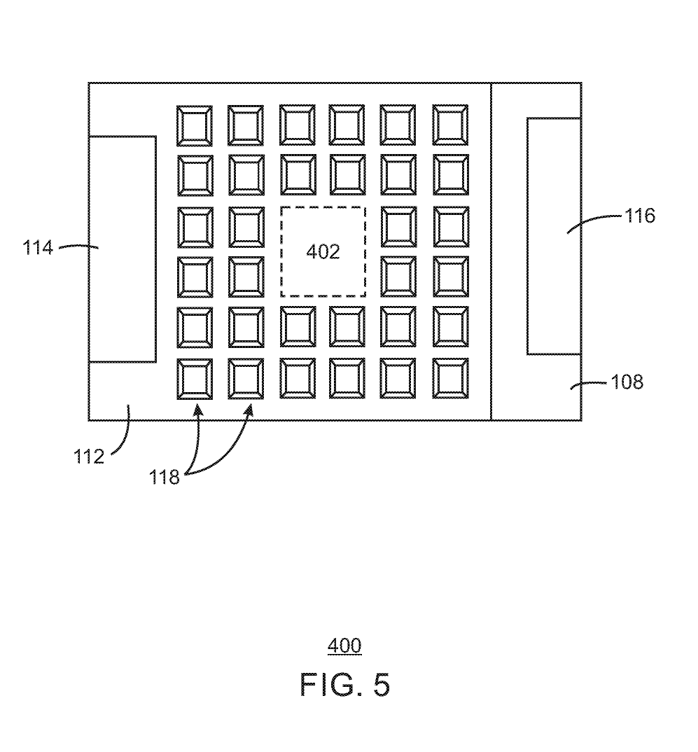

FIG. 5 is a top view of the example LED shown in FIG. 4. FIG. 5 more clearly shows the open area 402 that is void of reflectors. Rather than a completely filled grid, the reflectors 118 are arranged around the perimeter of the window layer 112. In an actual implementation, the size of the open area may be larger or smaller than shown in FIG. 5. For example, although FIG. 5 shows two rows of reflectors 118 disposed around the perimeter of the window layer 112, other implementations may include one, three, four, five rows, or more. The illumination pattern of the LED 400 may be controlled, in part, by controlling the number and spatial arrangement of the reflectors 118.

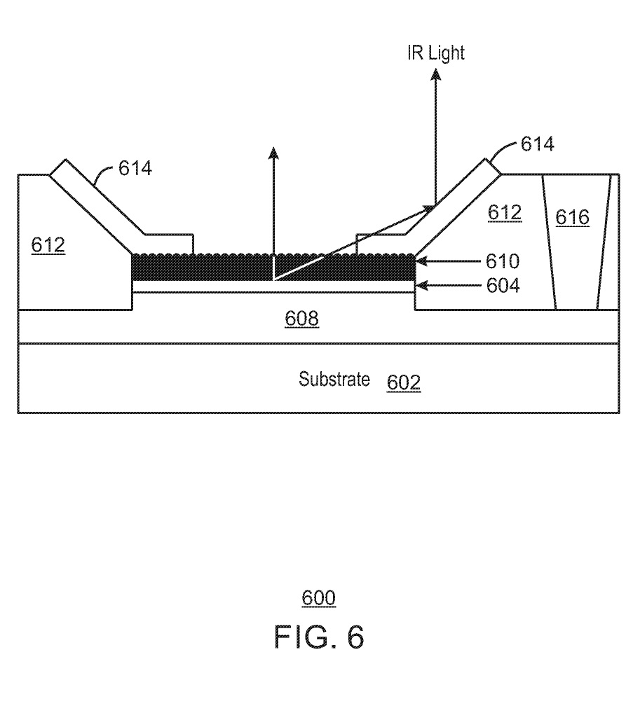

FIG. 6 is a cross sectional view of another example LED with built-in features that enable the LED to exhibit a specified illumination pattern. The example LED 600 includes a substrate layer 602 and a quantum well layer 604 disposed between an N-type layer 608 and a P-type layer 610. The P-type layer 610 serves as a transparent window and allows light to be emitted from the quantum well layer 604. The P-type layer 610 may be formed in a manner that provides a rough surface, as shown in FIG. 6. For example, the rough surface may be obtained by wet etching. The rough surface allows light to be emitted from the P-type layer 610 at various angles. The fabrication techniques described above in relation to FIG. 1 may also apply to the layers of the LED 600. However, rather than shaping the window layer (P-type layer 610) to create desired illumination pattern, the window layer is left rough and relatively flat. Additionally, an oxide layer 612 is disposed around the outer circumference of the quantum well 604 and the P-type layer 610.

The height of the oxide layer 612 above the P-type layer 610 causes the surface of the window layer to sit at the base of a depression with sloping walls. A conductive layer 614 is disposed along the walls of the depression. The conductive layer 614 serves as the P-type electrical contact and also serves to reflect the light emitted by the quantum well layer 604. In some examples, the conductive layer 614 is transparent. Contact with the N-type layer 608 is enabled through a contact via 616. The conductive layers 614 and 616 may be a layer of metal such as Indium-Tin-Oxide (ITO), Zinc Oxide (ZnO), or doped versions of ZnO (i.e., doped with Sulfur, Aluminum, etc). In the example LED 600 of FIG. 6, the illumination pattern of the LED 600 may be controlled, in part, by controlling the slope and the height of the conductive layer 614.

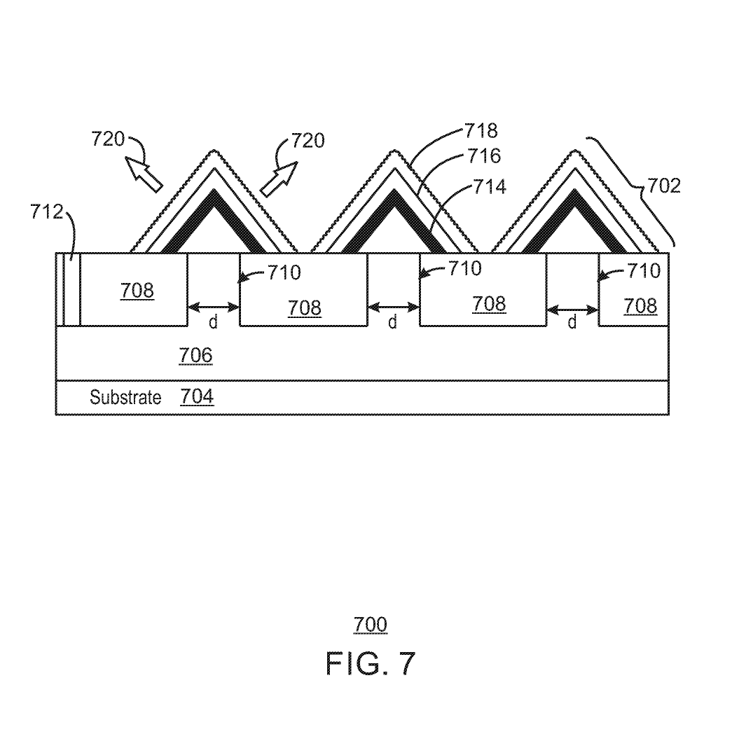

FIG. 7 is a cross sectional view of another example LED with built-in features that enable the LED to exhibit a specified illumination pattern. The LED 700 is made of several separate LED elements 702. The LED 700 includes a substrate 704 such as Gallium Arsenide (GaAs). An N-type layer 706 is disposed over the substrate 704 and an insulator 708 such as Silicon Nitride (Si₃N₄) is disposed over the N-type layer 706. The insulator 708 includes several vias 710, each of which is filled with N-type material and couples one of the LED elements 702 to the N-type layer 706. Another N-type via 712 contains a conductive material such as metal that enables electrical contact with the N-type layer 706.

Each LED element 702 projects from the surface of the insulator 708 and includes a quantum well layer 714 disposed over the N-type material. The LED elements 702 also include a P-type layer 716 such as Aluminum Arsenide (AlAs) disposed over the quantum well layer 714. A transparent P-type metal layer 718 is disposed over the P-type layer 716 to provide an electrical contact with the P-type layer 716. The application of a sufficient voltage to the transparent P-type metal layer 718 and the N-type via 712 will cause the quantum well layer 714 to emit light. The transparent P-type metal layer 718 may be formed in a manner that provides a rough surface, as shown in FIG. 7. For example, the rough surface may be obtained by wet etching. The rough surface allows light to be emitted from the transparent P-type metal layer 718 at various angles.

The illumination level of the light passing through the transparent P-type metal will be more intense in the direction normal to the plane of the transparent P-type metal as shown by arrows 720. The illumination pattern of the LED 700 may be controlled, in part, by controlling the slope and the height of the LED elements 702.

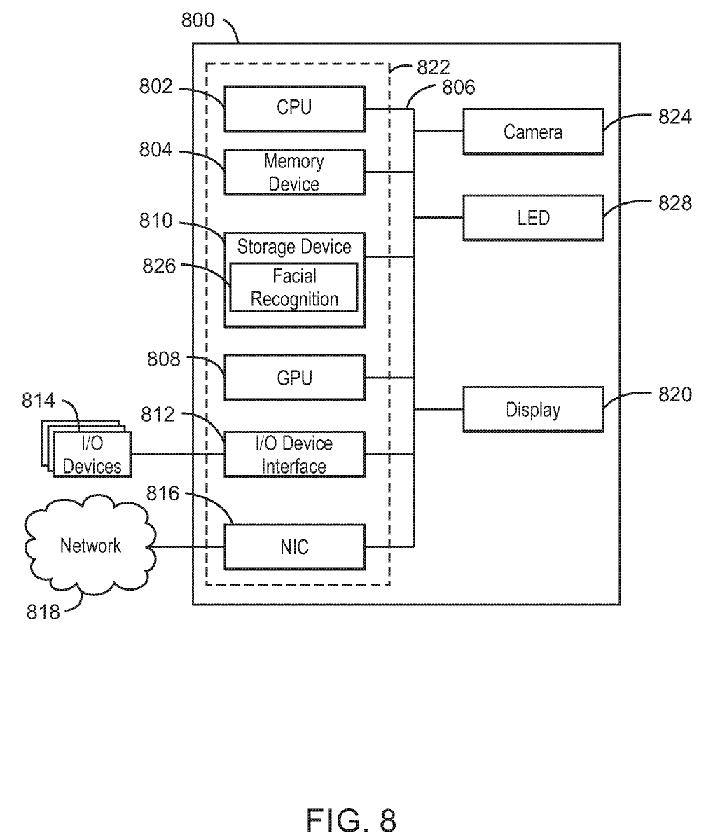

FIG. 8 is a block diagram of an electronic device equipped with one of the LEDs described herein. The electronic device 800 may be a laptop computer, tablet computer, mobile phone, smart phone, or any other suitable electronic device. The electronic device 800 may include a central processing unit (CPU) 802 that is configured to execute stored instructions, as well as a memory device 804 that stores instructions that are executable by the CPU 802. The CPU 802 may be coupled to the memory device 804 by a bus 806. The CPU 802 may be a single core processor, a multi-core processor, a computing cluster, or any number of other configurations. The CPU 802 may be implemented as a Complex Instruction Set Computer (CISC) processor, a Reduced Instruction Set Computer (RISC) processor, x86 Instruction set compatible processor, or any other microprocessor or central processing unit (CPU). In some embodiments, the CPU 802 includes dual-core processor(s), dual-core mobile processor(s), or the like.

The memory device 804 may include random access memory (e.g., SRAM, DRAM, zero capacitor RAM, SONOS, eDRAM, EDO RAM, DDR RAM, RRAM, PRAM, etc.), read only memory (e.g., Mask ROM, PROM, EPROM, EEPROM, etc.), flash memory, or any other suitable memory system. The memory device 804 can be used to store data and computer-readable instructions that, when executed by the CPU 802, direct the CPU 802 to perform various operations in accordance with embodiments described herein. The electronic device 800 may also include a graphics processing unit (GPU) 808. The GPU 808 may be configured to perform any number of graphics operations.

The electronic device 800 may also include a storage device 810. The storage device 810 is a physical memory device such as a hard drive, an optical drive, a flash drive, an array of drives, or any combinations thereof. The storage device 810 may store programming code such as device drivers, software applications, operating systems, and the like. The programming code stored by the storage device 810 may be executed by the CPU 802, GPU 808, or any other processors that may be included in the electronic device 800.

The electronic device 800 may also include an input/output (I/O) device interface 812 configured to connect the electronic device 800 to one or more I/O devices 814. For example, the I/O devices 814 may include a printer, a scanner, a keyboard, and a pointing device such as a mouse, touchpad, or, touchscreen, among others. The I/O devices 814 may be built-in components of the electronic device 800, or may be devices that are externally connected to the electronic device 800.

The electronic device 800 may also include a network interface controller (NIC) 816 configured to connect the electronic device 800 to a network 818. The network 818 may be a wide area network (WAN), local area network (LAN), or the Internet, among others. The electronic device 800 may also include a display screen 820 for rendering graphics, images, video, and the like.

In some embodiments, the CPU 802, the memory device 804, the storage device 810, the GPU 808, the I/O device interface 812, and the NIC 816 may be integrated as a System-On-a-Chip (SOC) 822. In other embodiments, some of the components may be integrated on a single chip, while other components may be stand-alone.

The electronic device 800 may include a camera 824. The camera may be configured to capture images and/or video in the visible spectrum, Infrared (IR), Near-Infrared (NIR), or others. The term “near-infrared” is defined herein as any part of the light spectrum characterized by a wavelength of around 0.75 to around 1.4 micrometers. In some examples, the camera 824 is used for biometric security and may be used to obtain iris images or facial images for secure biometric authorization. The storage device 810 may include a facial recognition program 826 that can be used, for example, to provide secure access to the electronic device 800 or software applications or data that may be stored to the electronic device 800.

The electronic device 800 also includes an LED illuminator 828 that is configured to provide a desired illumination pattern such as the batwing pattern shown in FIG. 3. The LED illuminator 828 may be any one of the LEDs described herein, including the LEDs shown in FIGS. 1, 4, 6, and 7. The LED illuminator 828 may be configured to emit light at a specific electromagnetic spectrum depending on the intended use. For example, the LED illuminator 828 may be configured to emit near infrared light to illuminate a person's face so that the camera 824 can capture an image of the user's face to be processed by facial recognition software 826. The LED illuminator 828 may also be configured to emit visible light, infrared light, ultraviolet light or any other suitable spectrum of light.

The block diagram of FIG. 8 is not intended to indicate that the computing device 800 is to include all of the components shown in FIG. 8. Rather, the computing system 800 can include fewer or additional components not shown in FIG. 8, depending on the details of the specific implementation. Furthermore, any of the functionalities of the CPU 802 or the graphics processor 808 may be partially, or entirely, implemented in hardware and/or a processor. For example, the functionality may be implemented in any combination of Application Specific Integrated Circuits (ASICs), Field Programmable Gate Arrays (FPGAs), logic circuits, and the like. In addition, embodiments of the present techniques can be implemented in any suitable electronic device, including ultra-compact form factor devices, such as System-On-a-Chip (SOC), and multi-chip modules.

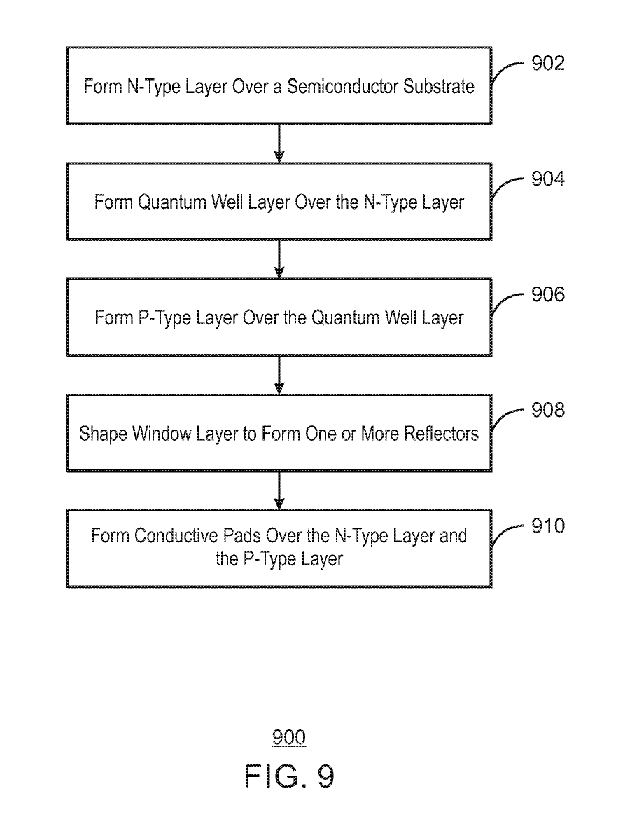

FIG. 9 is a process flow diagram summarizing an example method of fabricating an LED with micro-reflectors. The method may begin at block 902.

At block 902, an N-type layer is formed over a semiconductor substrate.

At block 904, a quantum well layer is formed over the N-type layer. As mentioned above, the quantum well layer may be a Multiple Quantum Well (MQL) that includes alternating layers of active material.

At block 906, a P-type layer is formed over the quantum well layer. In some examples, forming the P-type layer includes forming an etch stop layer over the quantum well layer and forming a window layer over the etch stop layer. In other examples, forming the P-type layer includes forming the window layer directly over the quantum well layer and the etch stop layer is omitted.

At block 908, the window layer is shaped to form one or more reflectors. The reflectors may be the reflective elements shown FIG. 1, 2, 4, or 5. However, other types of reflectors are also possible.

At block 910, conductive pads are formed over the N-type layer and the P-type layer. The conductive pads provide electrical contacts that enable the LED to be activated.

The method 900 should not be interpreted as meaning that the blocks are necessarily performed in the order shown. Furthermore, fewer or additional actions can be included in the method 900 depending on the design considerations of a particular implementation.

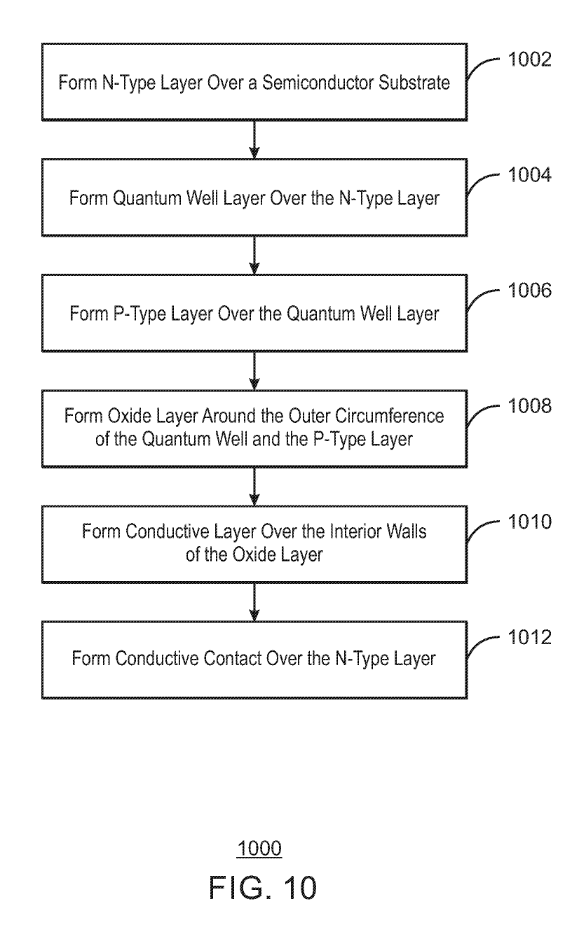

FIG. 10 is a process flow diagram summarizing another example method of fabricating an LED with built-in features that enable the LED to exhibit a specified illumination pattern. The LED 600 shown in FIG. 6 is an example of an LED that may be fabricated using the method 1000. The method 1000 may begin at block 1002.

At block 1002, an N-type layer is formed over a semiconductor substrate.

At block 1004, a quantum well layer is formed over the N-type layer. As mentioned above, the quantum well layer may be a Multiple Quantum Well (MQL) that includes alternating layers of active material.

At block 1006, a P-type layer is formed over the quantum well layer. In some examples, forming the P-type layer includes forming an etch stop layer over the quantum well layer and forming a window layer over the etch stop layer. In other examples, forming the P-type layer includes forming the window layer directly over the quantum well layer and the etch stop layer is omitted.

At block 1008, an oxide layer is formed around the outer circumference of the quantum well and the P-type layer, which includes the window layer. The oxide layer may be formed to extend above the height of the P-type layer so that the interior walls of the oxide layer surrounding the P-type layer are sloped. The formation of the interior walls of the oxide layer may be controlled to form a specified height and slope angle. The specified height and slope angle may selected to provide a desired illumination pattern.

At block 1010, a conductive layer is formed over the interior walls of the oxide layer. The conductive layer may also contact a portion of the top surface of the P-type layer so that the conductive layer can serve as electrical contact to the P-type layer that enables the LED to be activated.

At block 1012, a conductive contact is formed over the N-Type layer. For example, a via structure may be formed in the oxide layer to expose the N-type layer below. A conductive material may then be formed in the via structure to create the conductive contact.

The method 1000 should not be interpreted as meaning that the blocks are necessarily performed in the order shown. Furthermore, fewer or additional actions can be included in the method 1000 depending on the design considerations of a particular implementation.

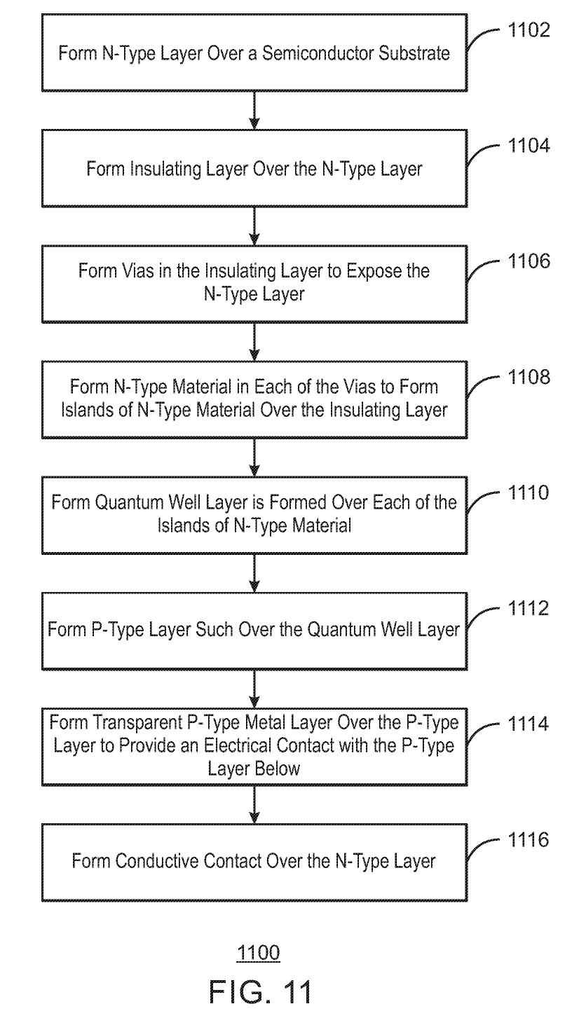

FIG. 11 is a process flow diagram summarizing another example method of fabricating an LED with built-in features that enable the LED to exhibit a specified illumination pattern. The LED 700 shown in FIG. 7 is an example of an LED that may be fabricated using the method 1100. The method 1100 may begin at block 1102.

At block 1102, an N-type layer is formed over a semiconductor substrate.

At block 1104, an insulating layer is formed over the N-type layer.

At block 1106, several vias are formed in the insulating layer to expose the N-type layer below. Each via will serve as the site of a separate LED element. Therefore, the number and arrangement via may be chosen depending on the desired number and arrangement of LED elements.

At block 1108, N-type material is formed in each of the vias. The N-type material may be formed so as to project above the surface of the insulating layer to form islands of N-type material over the insulating layer. The islands of N-type material are electrically isolated from one another. The shape and height of the islands may be controlled during formation to provide a predetermined shape and height that will provide a desired illumination pattern.

At block 1110, a quantum well layer is formed over each of the islands of N-type material. As mentioned above, the quantum well layer may be a Multiple Quantum Well (MQL) that includes alternating layers of active material.

At block 1112, a P-type layer such is formed over the quantum well layer.

At block 1114, a transparent P-type metal layer is formed over the P-type layer to provide an electrical contact with the P-type layer below. The transparent P-type metal layer can serve as electrical contact to the P-type layer that enables the LED to be activated.

At block 1116, a conductive contact is formed over the N-Type layer. For example, another via structure may be formed in the insulating layer to expose the N-type layer below. A conductive material may then be formed in the via structure to create the conductive contact.

The method 1100 should not be interpreted as meaning that the blocks are necessarily performed in the order shown. Furthermore, fewer or additional actions can be included in the method 1100 depending on the design considerations of a particular implementation.

### EXAMPLES

Example 1 is an image capture system. The system includes a camera to capture an image and a Light Emitting Diode (LED) to emit light for illuminating a target of the image. The LED includes a light emitting layer and a window layer. The window layer includes a transparent semiconductor material disposed over the light emitting layer. A shape of the window layer results in a reflective surface that generates a specified illumination pattern to reduce the effect of illuminance distortions created by the image capture system.

Example 2 includes the system of example 1, including or excluding optional features. In this example, the reflective surface includes a grid of raised reflectors.

Example 3 includes the system of any one of examples 1 to 2, including or excluding optional features. In this example, the reflective surface includes a grid of tetrahedron-shaped reflectors.

Example 4 includes the system of any one of examples 1 to 3, including or excluding optional features. In this example, the reflective surface includes a grid of pyramid-shaped reflectors.

Example 5 includes the system of any one of examples 1 to 4, including or excluding optional features. In this example, the reflective surface includes a plurality of reflectors disposed around a perimeter of the window layer.

Example 6 includes the system of any one of examples 1 to 5, including or excluding optional features. In this example, the reflective surface includes two or more rows of reflectors surrounding a flat area at a middle of the window layer.

Example 7 includes the system of any one of examples 1 to 6, including or excluding optional features. In this example, the system includes a conductive contact pad disposed over a portion of the window layer, wherein the LED is to be activated by application of a voltage to the contact pad.

Example 8 includes the system of any one of examples 1 to 7, including or excluding optional features. In this example, the reflective surface resulting from the shape of the window layer increases an illumination intensity at edges of a radiation pattern generated by the LED compared to a flat window layer.

Example 9 includes the system of any one of examples 1 to 8, including or excluding optional features. In this example, the reflective surface resulting from the shape of the window layer generates a batwing-style radiation pattern.

Example 10 includes the system of any one of examples 1 to 9, including or excluding optional features. In this example, the LED is to emit light in the Near-Infrared (NIR) spectrum.

Example 11 is a Light Emitting Diode (LED) with an integrated micro-reflector. The LED includes a light emitting layer and a window layer. The window layer includes transparent semiconductor material disposed over the light emitting layer. A shape of the window layer results in a reflective surface that generates a specified illumination pattern.

Example 12 includes the LED of example 11, including or excluding optional features. In this example, the reflective surface includes a grid of raised reflectors.

Example 13 includes the LED of any one of examples 11 to 12, including or excluding optional features. In this example, the reflective surface includes a grid of tetrahedron-shaped reflectors.

Example 14 includes the LED of any one of examples 11 to 13, including or excluding optional features. In this example, the reflective surface includes a grid of pyramid-shaped reflectors.

Example 15 includes the LED of any one of examples 11 to 14, including or excluding optional features. In this example, the reflective surface includes a plurality of reflectors disposed around a perimeter of the window layer.

Example 16 includes the LED of any one of examples 11 to 15, including or excluding optional features. In this example, the reflective surface includes two or more rows of reflectors surrounding a flat area at a middle of the window layer.

Example 17 includes the LED of any one of examples 11 to 16, including or excluding optional features. In this example, the LED includes a conductive contact pad disposed over a portion of the window layer, wherein the LED is to be activated by application of a voltage to the contact pad.

Example 18 includes the LED of any one of examples 11 to 17, including or excluding optional features. In this example, the reflective surface resulting from the shape of the window layer increases an illumination intensity at edges of a radiation pattern of the LED compared to a flat window layer.

Example 19 includes the LED of any one of examples 11 to 18, including or excluding optional features. In this example, the reflective surface resulting from the shape of the window layer generates a batwing-style radiation pattern.

Example 20 includes the LED of any one of examples 11 to 19, including or excluding optional features. In this example, the LED is to emit light in the Near-Infrared (NIR) spectrum.

Example 21 is a method of fabricating a Light Emitting Diode (LED) with an integrated micro-reflector. The method includes forming a light emitting layer; forming a window layer over the light emitting layer, wherein the window layer includes transparent semiconductor material; and shaping the window layer to form a reflective surface that generates a specified illumination pattern.

Example 22 includes the method of example 21, including or excluding optional features. In this example, shaping the window layer to form a reflective surface includes forming a grid of raised reflectors.

Example 23 includes the method of any one of examples 21 to 22, including or excluding optional features. In this example, shaping the window layer to form a reflective surface includes forming a grid of tetrahedron-shaped reflectors.

Example 24 includes the method of any one of examples 21 to 23, including or excluding optional features. In this example, shaping the window layer to form a reflective surface includes forming a grid of pyramid-shaped reflectors.

Example 25 includes the method of any one of examples 21 to 24, including or excluding optional features. In this example, the method includes forming a conductive contact pad over a portion of the window layer, wherein the LED is to be activated by application of a voltage to the contact pad.

Example 26 is a Light Emitting Diode (LED) with an integrated micro-reflector. The LED includes a light emitting layer and a window layer. The window layer includes a transparent semiconductor material disposed over the light emitting layer; an oxide layer disposed around an outer circumference of the window layer to form a depression with sloping walls, wherein the window layer sits at a base of the depression; and a conductive layer disposed over the oxide layer along the sloping walls of the depression, wherein the conductive layer forms a reflective surface that reflects light emitted through the window layer.

Example 27 includes the LED of example 26, including or excluding optional features. In this example, a slope of the sloping walls of the depression is controlled to generate a specified illumination pattern. Optionally, the specified illumination pattern is a batwing-style radiation pattern.

Example 28 includes the LED of any one of examples 26 to 27, including or excluding optional features. In this example, the LED is configured to be activated by applying a voltage to the conductive layer.

Example 29 includes the LED of any one of examples 26 to 28, including or excluding optional features. In this example, the LED is to emit light in the Near-Infrared (NIR) spectrum.

Example 30 is a method of fabricating a Light Emitting Diode (LED) with an integrated micro-reflector. The method includes forming a light emitting layer; forming a window layer over the light emitting layer, the window layer including transparent semiconductor material; forming an oxide layer around an outer circumference of the window layer to form a depression with sloping walls, wherein the window layer sits at a base of the depression; and forming a conductive layer over the oxide layer along the sloping walls of the depression, wherein the conductive layer forms a reflective surface that reflects light emitted through the window layer.

Example 31 includes the method of example 30, including or excluding optional features. In this example, the LED is to be activated by application of a voltage to the conductive layer.

Example 32 includes the method of any one of examples 30 to 31, including or excluding optional features. In this example, forming the oxide layer includes controlling a slope of the sloping walls to generate a specified illumination pattern. Optionally, the specified illumination pattern is a batwing-style radiation pattern.

Example 33 is a Light Emitting Diode (LED). The LED includes an N-type layer disposed over a semiconductor substrate; an insulator layer disposed above the N-type layer; a plurality of LED elements projecting above a surface of an insulator, wherein the plurality of LED elements is isolated from each other. Each LED element of the plurality of LED elements includes: a light emitting layer; a P-type layer disposed over the light emitting layer; and a transparent P-type metal layer disposed over the P-type layer.

Example 34 includes the LED of example 33, including or excluding optional features. In this example, the LED includes a plurality of N-type through vias disposed in the insulator layer, wherein each one of the plurality of N-type through vias couples the N-type layer to a respective one of the plurality of LED elements.

Example 35 includes the LED of any one of examples 33 to 34, including or excluding optional features. In this example, a shape of the LED element is controlled to generate a specified illumination pattern. Optionally, the specified illumination pattern is a batwing-style radiation pattern.

Example 36 includes the LED of any one of examples 33 to 35, including or excluding optional features. In this example, the LED is configured to be activated by applying a voltage to the transparent P-type metal layer.

Example 37 includes the LED of any one of examples 33 to 36, including or excluding optional features. In this example, the LED is to emit light in the Near-Infrared (NIR) spectrum.

Example 38 is a method of fabricating a Light Emitting Diode (LED). The method includes forming an N-type layer over a semiconductor substrate; forming an insulator layer over the N-type layer; forming a plurality of LED elements that project above a surface of an insulator, wherein the plurality of LED elements is isolated from each other. Forming each LED element of the plurality of LED elements includes: forming a light emitting layer; forming a P-type layer over the light emitting layer; and forming a transparent P-type metal layer over the P-type layer.

Example 39 includes the method of example 38, including or excluding optional features. In this example, forming each LED element of the plurality of LED elements includes forming a plurality of N-type through vias in the insulator layer, and forming each one of the plurality of LED elements over a respective one of the plurality of N-type through vias.

Example 40 includes the method of any one of examples 38 to 39, including or excluding optional features. In this example, forming each LED element of the plurality of LED elements includes controlling a shape of the LED element to generate a specified illumination pattern. Optionally, the specified illumination pattern is a batwing-style radiation pattern.

Example 41 includes the method of any one of examples 38 to 40, including or excluding optional features. In this example, the LED is configured to be activated by applying a voltage to the transparent P-type metal layer.

Some embodiments may be implemented in one or a combination of hardware, firmware, and software. Some embodiments may also be implemented as instructions stored on the tangible, non-transitory, machine-readable medium, which may be read and executed by a computing platform to perform the operations described. In addition, a machine-readable medium may include any mechanism for storing or transmitting information in a form readable by a machine, e.g., a computer. For example, a machine-readable medium may include read only memory (ROM); random access memory (RAM); magnetic disk storage media; optical storage media; flash memory devices; or electrical, optical, acoustical or other form of propagated signals, e.g., carrier waves, infrared signals, digital signals, or the interfaces that transmit and/or receive signals, among others.

An embodiment is an implementation or example. Reference in the specification to “an embodiment,” “one embodiment,” “some embodiments,” “various embodiments,” or “other embodiments” means that a particular feature, structure, or characteristic described in connection with the embodiments is included in at least some embodiments, but not necessarily all embodiments, of the present techniques. The various appearances of “an embodiment,” “one embodiment,” or “some embodiments” are not necessarily all referring to the same embodiments.

Not all components, features, structures, characteristics, etc. described and illustrated herein need be included in a particular embodiment or embodiments. If the specification states a component, feature, structure, or characteristic “may”, “might”, “can” or “could” be included, for example, that particular component, feature, structure, or characteristic is not required to be included. If the specification or claim refers to “a” or “an” element, that does not mean there is only one of the element. If the specification or claims refer to “an additional” element, that does not preclude there being more than one of the additional element.

It is to be noted that, although some embodiments have been described in reference to particular implementations, other implementations are possible according to some embodiments. Additionally, the arrangement and/or order of circuit elements or other features illustrated in the drawings and/or described herein need not be arranged in the particular way illustrated and described. Many other arrangements are possible according to some embodiments.

In each system shown in a figure, the elements in some cases may each have a same reference number or a different reference number to suggest that the elements represented could be different and/or similar. However, an element may be flexible enough to have different implementations and work with some or all of the systems shown or described herein. The various elements shown in the figures may be the same or different. Which one is referred to as a first element and which is called a second element is arbitrary.

It is to be understood that specifics in the aforementioned examples may be used anywhere in one or more embodiments. For instance, all optional features of the computing device described above may also be implemented with respect to either of the method or the computer-readable medium described herein. Furthermore, although flow diagrams and/or state diagrams may have been used herein to describe embodiments, the techniques are not limited to those diagrams or to corresponding descriptions herein. For example, flow need not move through each illustrated box or state or in exactly the same order as illustrated and described herein.

The present techniques are not restricted to the particular details listed herein. Indeed, those skilled in the art having the benefit of this disclosure will appreciate that many other variations from the foregoing description and drawings may be made within the scope of the present techniques. Accordingly, it is the following claims including any amendments thereto that define the scope of the present techniques.

What is claimed is:

1. An image capture system comprising:
a camera to capture an image; and
a Light Emitting Diode (LED) to emit light for illuminating a target of the image, the LED comprising a light emitting layer and a window layer, the window layer comprising transparent semiconductor material disposed over the light emitting layer;
wherein a shape of the window layer results in a reflective surface that generates a specified illumination pattern to reduce the effect of illuminance distortions created by the image capture system.

2. The image capture system of claim 1, wherein the reflective surface comprises a grid of raised reflectors.

3. The image capture system of claim 1, wherein the reflective surface comprises a grid of tetrahedron-shaped reflectors.

4. The image capture system of claim 1, wherein the reflective surface comprises a grid of pyramid-shaped reflectors.

5. The image capture system of claim 1, wherein the reflective surface comprises a plurality of reflectors disposed around a perimeter of the window layer.

6. The image capture system of claim 1, wherein the reflective surface comprises two or more rows of reflectors surrounding a flat area at a middle of the window layer.

7. The image capture system of claim 1, comprising a conductive contact pad disposed over a portion of the window layer, wherein the LED is to be activated by application of a voltage to the contact pad.

8. The image capture system of claim 1, wherein the reflective surface resulting from the shape of the window layer increases an illumination intensity at edges of a radiation pattern generated by the LED compared to a flat window layer.

9. The image capture system of claim 1, wherein the reflective surface resulting from the shape of the window layer generates a batwing-style radiation pattern.

10. The image capture system of claim 1, wherein the LED is to emit light in the Near-Infrared (NIR) spectrum.

11. A Light Emitting Diode (LED) with an integrated micro-reflector comprising:
a light emitting layer and a window layer, the window layer comprising transparent semiconductor material disposed over the light emitting layer;
wherein a shape of the window layer results in a reflective surface that generates a specified illumination pattern.

12. The LED of claim 11, wherein the reflective surface comprises a grid of raised reflectors.

13. The LED of claim 11, wherein the reflective surface comprises a grid of tetrahedron-shaped reflectors.

14. The LED of claim 11, wherein the reflective surface comprises a grid of pyramid-shaped reflectors.

15. The LED of claim 11, wherein the reflective surface comprises a plurality of reflectors disposed around a perimeter of the window layer.

16. The LED of claim 11, wherein the reflective surface comprises two or more rows of reflectors surrounding a flat area at a middle of the window layer.

17. The LED of claim 11, comprising a conductive contact pad disposed over a portion of the window layer, wherein the LED is to be activated by application of a voltage to the contact pad.

18. The LED of claim 11, wherein the reflective surface resulting from the shape of the window layer increases an illumination intensity at edges of a radiation pattern of the LED compared to a flat window layer.

19. The LED of claim 11, wherein the reflective surface resulting from the shape of the window layer generates a batwing-style radiation pattern.

20. The LED of claim 11, wherein the LED is to emit light in the Near-Infrared (NIR) spectrum.

21. A method of fabricating a Light Emitting Diode (LED) with an integrated micro-reflector comprising:
forming a light emitting layer;
forming a window layer over the light emitting layer, the window layer comprising transparent semiconductor material; and
shaping the window layer to form a reflective surface that generates a specified illumination pattern.

22. The method of claim 21, wherein shaping the window layer to form a reflective surface comprises forming a grid of raised reflectors.

23. The method of claim 21, wherein shaping the window layer to form a reflective surface comprises forming a grid of tetrahedron-shaped reflectors.

24. The method of claim 21, wherein shaping the window layer to form a reflective surface comprises forming a grid of pyramid-shaped reflectors.

25. The method of claim 21, comprising forming a conductive contact pad over a portion of the window layer, wherein the LED is to be activated by application of a voltage to the contact pad.
